(19) United States
(12) Patent Application Publication
(10) Pub. No.: US 2009/0039345 A1
(43) Pub. Date: Feb. 12, 2009

(54) Tunnel Junction Barrier Layer Comprising a Diluted Semiconductor with Spin Sensitivity

(75) Inventor: Fredrik Gustavsson, Nacka (SE)

Correspondence Address: LADAS & PARRY LLP, 224 SOUTH MICHIGAN AVENUE, SUITE 1600, CHICAGO, IL, 60604, US

(73) Assignee: NM Spintronics AB, Stockholm (SE)

(21) Appl. No.: 11/596,549

(22) PCT Filed: May 23, 2005
(86) PCT No.: PCT/SE05/00755

§ 371 Date: Nov. 15, 2006

(30) Foreign Application Priority Data
May 25, 2004 (SE) 0401392-6

(51) Int. Cl. H01L 29/43

(52) U.S. Cl. 257/43; 257/E29.139

(57) ABSTRACT

The invention provides a magnetic tunnel junction having a tunneling barrier layer wherein said tunneling barrier layer comprises a diluted magnetic semiconductor with spin sensitivity. The magnetic tunnel junction may according to the invention comprise a bottom lead coupled to a bottom electrode which is coupled to a diluted magnetic semiconductor coupled to a top electrode being coupled to a top lead, wherein said bottom electrode is non magnetic. The invention further provides various components and a computer, exploiting the magnetic tunnel junction according to the invention.

### TECHNICAL FIELD OF THE INVENTION

The invention relates to Magnetic Tunnel Junction (MTJ) devices for spin-sensitive electronic and optical applications. These applications include non-volatile magnetic random access memories (MRAMs), magneto resistive read heads for magnetic disk drives, spin-valve/magnetic-tunnel transistors, ultra-fast optical switches and light emitters with polarization modulated output. Other applications, within which the invention can be incorporated as a sub-system, are logic devices with variable logic function and quantum computers. In particular, the invention uses a tunnel barrier with a spin-filter function to improve the properties and performance of MTJs.

### BACKGROUND OF THE INVENTION

Magnetic Tunnel Junctions (MTJs) are devices that exploit the magneto resistance effect to modulate electrical conductivity. A MTJ device comprises two ferromagnetic electrodes separated by an insulating barrier layer made sufficiently thin to allow quantum-mechanical tunneling of charge carriers to occur between the electrodes (FIG. 1 (a)). Within the electrodes, the charge carriers are spin-polarised as a consequence of the magnetic properties. The majority of spins align with the magnetization direction of each electrode, respectively. Since the tunneling process is spin dependent, the magnitude of the tunnel current is a function of the relative orientation of magnetization between the two electrodes. By using electrodes with different responses to magnetic fields, the relative orientation of magnetization can be controlled by an external magnetic field of appropriate strength. Typically, the tunnel current peaks for parallel alignment of the electrodes whereas it reaches a minimum for anti-parallel alignment. MTJs find their use particularly as memory cells in non-volatile memory arrays such as MRAMs and as magnetic field sensors in, for example, magneto resistive read heads for magnetic recording disk drives.

The signal-to-noise ratio is of key importance for the performance of MTJ device applications. The signal magnitude is primarily determined by the magneto resistance (MR) ratio ΔR/R exhibited by the device, where ΔR is the difference in resistance between two magnetic configurations. Defining the signal as a voltage output, the magnitude of the signal is given by Ib×ΔR, where Ib is a constant-bias tunneling current passing through the device. Regarding noise, the noise level increases with increased device resistance R. Consequently, to achieve optimal performance of MTJ devices, a large MR ratio along with a small device resistance are essential. Below it will be described how the former quantity relates to the spin-polarization of the ferromagnetic electrodes and the latter quantity to the properties of the insulating barrier.

A high MR ratio requires highly spin-polarised electrode layers. The relation between MR and the spin-polarization P of the electrodes can be described by the following, frequently employed, approximation [1]

ΔR/R=2P₁P₂/(1−P₁P₂), (1)

where P₁ and P₂ are the spin polarizations of the top and bottom electrode in the MTJ device, respectively. The ferromagnetic transition metals Fe, Co and Ni and alloys thereof represent typical materials used as spin-polarised electrode layers in conventional MTJs. The maximum spin-polarization achievable with these materials is about 50% [2]. Thus, for two electrodes with a spin-polarization P=50%, the maximum obtainable MR is 67% according to Eq. (1). This can be considered as a fundamental limit for the MR in conventional MTJ devices and compares reasonably well with what has been reported so far. Typical MR values achieved for MTJs at room temperature using the aforementioned electrode materials are 20-40% and at best up to about 60%, albeit rare. Because of the constantly growing demand for higher MR effects, many efforts have been made to go beyond this limit. For example, alternative electrode materials such as the so-called half-metallic ferro magnets with predicted spin-polarization of close to 100% [3] have been attempted but true half metals have been proven to be extremely difficult to realize in practice [4].

The resistance of a MTJ device is predominantly determined by the resistance of the insulating tunnel barrier layer since the resistance of the electrical leads and the ferromagnetic electrodes contribute little to the resistance. Therefore, the barrier layer resistance is also the main source of noise in a MTJ device. Furthermore, the resistance scales with the inverse of the lateral area of the device since the current is passed perpendicular to the layer planes. For high density applications such as MRAM arrays, this becomes crucial as the signal-to-noise ratio deteriorates with decreasing areas of the MTJ cells. It is common to describe the MTJ resistance as the resistance R times the area A (RA). The RA product for the insulating barrier can be expressed in a simplified way as

RA∝e^{2d\sqrt{φ}}, (2)

where d is the thickness of the barrier and φ the tunnel barrier height (FIG. 1 (b)). For the sake of clarity, the constant \sqrt{2 m/h²} has been omitted from the exponential term. Thus, the resistance increases exponentially with both d and φ and in order to reduce the MTJ resistance, the barrier thickness and/or the barrier height must be made smaller. For MRAM applications, two signal states of the device need to be detected and RA values of 500-1000 Ωμm² yield acceptable signal-to-noise ratios. On the other hand, for magneto resistive read head applications, a continuous range of signal states must be detectable and RA values of the order 10 Ωμm² or less are required in order to be competitive with today's metallic giant magneto resistive heads. In prior art, the insulating barrier layer in MTJs consist of alumina, Al₂O₃. Alumina is a stable oxide insulator that can be made very thin with a maintained high degree of layer continuity. To meet the above RA ranges, it turns out that the alumina barrier thickness needs to be made ultra thin, about 1 nm for MRAMs and 0.6-0.7 nm for read heads. At this thickness regime the MR is typically degraded, most likely due to the formation of quantum point defects and/or microscopic pin holes in the ultra thin tunnel barrier layer needed to obtain these very low RA values. What mainly forces the alumina barrier thickness into this ultra thin regime is the large barrier height φ of 2.3-3 eV that is formed with conventional ferromagnetic electrode materials.

Thus, for further improvements of MTJ devices, ways to both increase the spin-polarization and to reduce the barrier resistance without degrading the MR must be found. Considering the limitations described above, this suggests a departure from the conventional MTJ structure as the appropriate course of action.

### SUMMARY OF THE INVENTION

The invention is a magnetic tunnel junction in which the prior art alumina tunneling barrier layer is replaced by a tunneling barrier layer consisting of a ferromagnetic semiconductor with lower barrier height and with a spin filter function. Since spin sensitivity thereby is introduced in the barrier layer, this allows a replacement of one of the ferromagnetic electrodes of prior art to a non-magnetic electrode. A MTJ device comprising such a spin filter barrier with a low effective barrier height promises enhancement of the MR effect with tunable resistance and a simpler MTJ device structure. Even though the invention has been summarized above, the invention is defined by the enclosed claims 1-10.

For full perception of the above mentioned features and additional features of the present invention, reference should be made to the following detailed description with accompanying figures.

### BRIEF DESCRIPTION OF DRAWINGS AND DIAGRAMS

FIG. 1a illustrates a cross section of a conventional MTJ device,

FIG. 1b illustrates a corresponding energy diagram for a tunneling barrier of the MTJ device illustrated in FIG. 1a.

FIG. 2a illustrates a cross section of a spin filter barrier MTJ device according to the invention,

FIG. 2b illustrates a corresponding energy diagram of the spin-filter barrier MTJ device illustrated in FIG. 2a.

FIG. 3 illustrates a calculated polarisation efficiency as function of the energy splitting of the spin-filter barrier in the proposed MTJ device illustrated in FIG. 2. In the calculation, a fixed barrier height φ=1 eV has been used and the polarization efficiency is calculated for three different barrier thicknesses, d=1, 2 and 3 nm, respectively.

FIG. 4 illustrates a calculated polarisation efficiency as function of the energy splitting of the spin-filter barrier in the proposed MTJ device illustrated in FIG. 2. In the calculation, a fixed barrier thickness d=2 nm has been used and the polarization efficiency is calculated for three different barrier heights, φ=0.5, 1 and 1.5 eV, respectively.

### DESCRIPTION OF THE PREFERRED EMBODIMENT

Conventional MTJ devices offer little room for further improvements due to the restricted spin-polarization of the electrodes and the high RA of the alumina barrier. In particular, much effort has been put down to develop efficient methods to reduce the alumina barrier thickness to the ultra-thin regime with preserved barrier uniformity. This has shown to be extremely difficult. The present invention comprises an alternative type of MTJ device structure that has the potential to provide a higher spin-polarization at reduced RA values compared to the conventional MTJ device

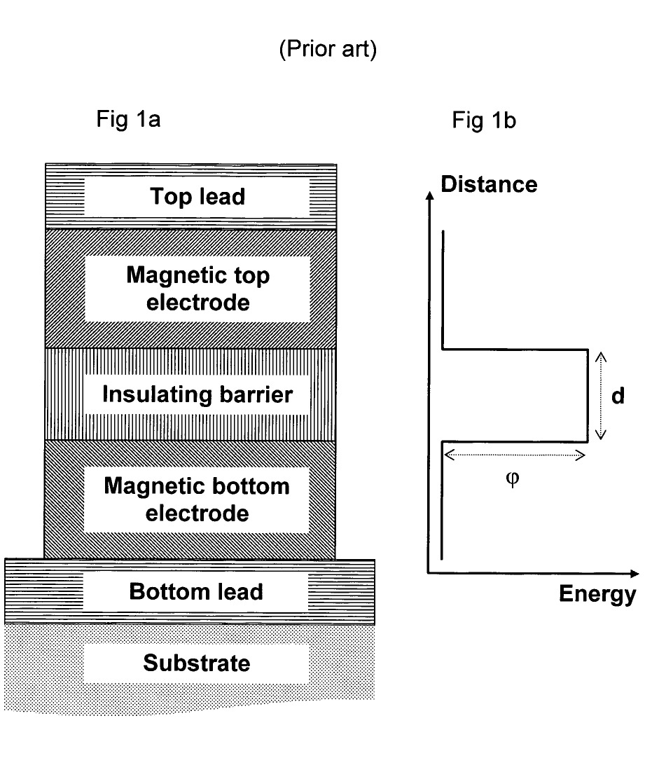

FIG. 1 (a) shows the cross-sectional MTJ device structure of prior art. The bottom ferromagnetic electrode layer (“fixed” layer), in most cases Co, is usually grown onto an antiferromagnetic layer (not shown) such as CoO that via exchange bias establishes a permanent magnetization direction of the bottom ferromagnetic electrode. The purpose of this is to make the bottom electrode insensitive to externally applied fields. On the other hand, the top electrode (“free” layer) is made of a soft magnetic material such as permalloy (NiFe) so that its magnetization direction can be easily altered by an external magnetic field. In this way, the relative orientation of magnetization between the two layers can be controlled. The barrier consists in the vast majority of cases of a thin layer of amorphous alumina. Electrical leads connect to the bottom and top electrode layer and the current is passed perpendicular to the layers. The MR effect in this device manifests itself as a change in resistance depending on the relative orientation of the magnetization between the top “free” layer and the “fixed” bottom layer.

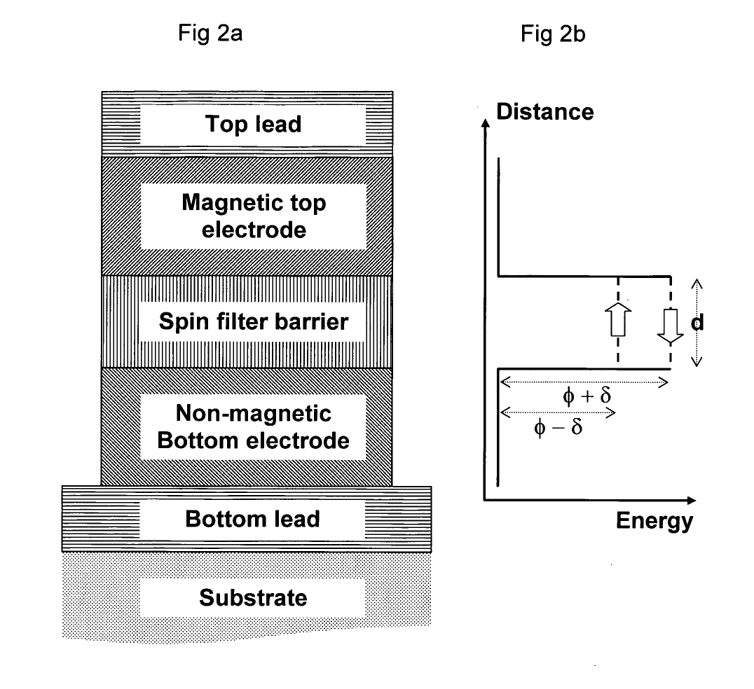

FIG. 2 (a) shows the cross-sectional MTJ device structure of the present invention. The device consists of a spin-filter tunneling barrier sandwiched between a bottom non-magnetic electrode and a top ferromagnetic electrode. The non-magnetic electrode consists of any conducting material and is not restricted to metals. The top ferromagnetic “free” layer electrode consists of a soft magnetic material in which the magnetization can be easily manipulated by an external field. The spin filter barrier material may consist of a wide band-gap semiconductor doped with metallic elements that induce ferromagnetism in the, intrinsically non-magnetic, semiconductor host crystal. These types of materials are referred to as diluted magnetic semiconductors. In contrast to the conventional MTJ device, the “fixed” layer is represented by the spin filter barrier and the MR effect manifests itself as a change in resistance depending on the relative magnetization orientation between the top “free” layer and the barrier. Below, a more detailed description of the ferromagnetic semiconductor barrier properties will follow.

The ferromagnetism in the semiconductor crystal is mediated by spin-polarised charge carriers between the metallic impurities. This causes a spin-dependent energy splitting of the conduction band. In other words, the conduction band edge is lower for one spin orientation compared to the opposite spin orientation. This situation is illustrated by the energy diagram in FIG. 2 (b), when the ferromagnetic semiconductor is comprised as barrier layer in the MTJ device. In the diagram, a barrier of average height φ is split into two spin-dependent sub-bands separated by and energy 26. Now, the charge carriers that are about to tunnel from one electrode to the other will face two different barrier heights, one for spin up and one for spin down. Since the tunneling process depends sensitively on the barrier height, the splitting of the conduction band greatly increases the probability of tunneling for spin up electrons. In contrast to the barrier resistance given in Eq. (2) for the unpolarised barrier, the spin-filter barrier resistance becomes divided into two spin components

RA [symbol] ∝e^{2d\sqrt{φ-δ}}

RA [symbol] ∝e^{2d\sqrt{φ+δ}} (3)

In a similar way as the spin-polarization P for ferromagnets is defined [1], a polarization efficiency PB for the spin filter barrier can be written as

P_{B}=(RA [symbol] −RA [symbol] )/(RA [symbol] +RA [symbol] ) (4)

In order to estimate the polarization efficiency, the spin filter barrier will be exemplified by a ferromagnetic semiconductor comprising ZnO as the wide band-gap (Eg=3.2 eV) semiconductor host and a metallic element (ME) that induces ferromagnetism. This ferromagnetic semiconductor will henceforth be referred to as ZnMEO. Other magnetic semiconductor materials could also be used.

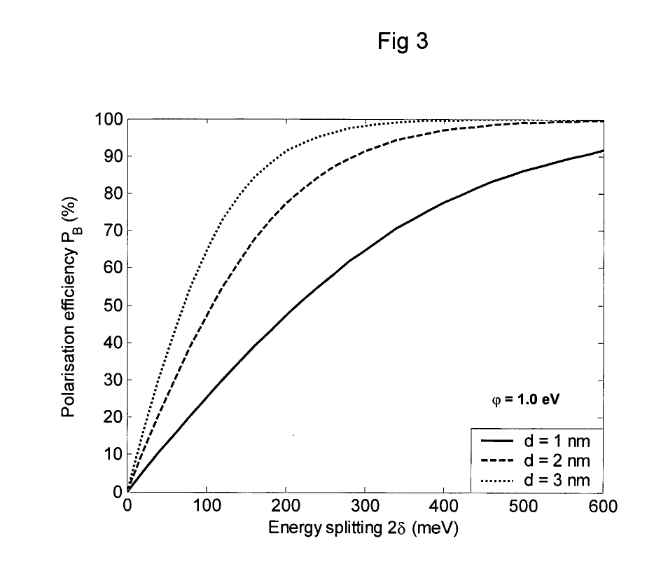

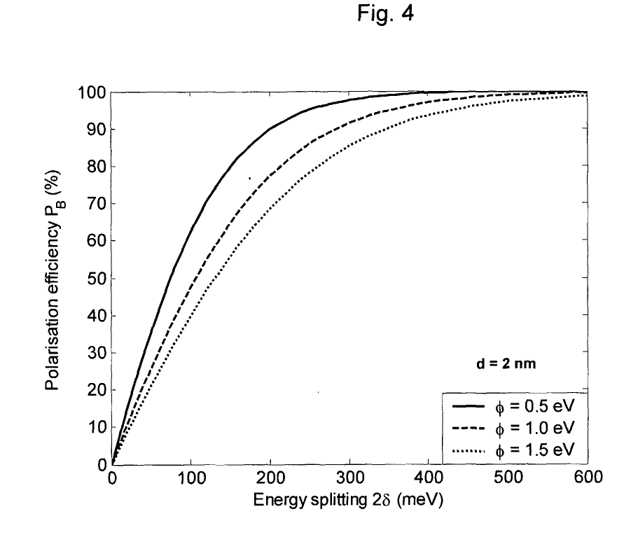

FIG. 3-4 show calculated polarization efficiencies PB as using eq. 4 for various barrier parameters as function of the energy splitting 2δ. In FIG. 3, the barrier height is fixed at 1 eV, which represents a typical barrier height between metals contacts and wide band-gap semiconductors, and the barrier thickness d is varied between 1 and 3 nm. In FIG. 4, the barrier thickness d is fixed at 2 nm and the barrier height φ is varied between 0.5 and 1.5 eV. To briefly conclude the results of FIGS. 3 and 4, the polarization efficiency increases with increasing barrier thickness and decreasing barrier height. The actual value of the energy splitting in ZnMEO depends on the type of ME used and the level of doping. Due to the recent discovery of room temperature ferromagnetism in these types of materials, no reported values are accessible at present. However, the extensively investigated insulator EuS becomes ferromagnetic at low temperature and thus represents a similar materials class to ZnMEO. In EuS, the spin dependent energy splitting of the conduction band is 360 meV [5]. Assuming that the energy splitting in ZnMEO is only half that of EuS, i.e., 180 eV, and using a barrier height of 1 eV, the polarization efficiency for a 2 nm thick ZnMEO spin filter barrier is about 73% according to FIG. 3. In order to estimate the MR exhibited by the present invention embodied in FIG. 1, a reference is made to eq 1. As opposed to the conventional MTJ, the present invention uses one non-magnetic bottom electrode and the spin sensitivity is rather introduced in the barrier layer. Therefore, the term P2 in eq. 1 is replaced by the spin filter efficiency PB. Using PB=73%, according to the preceding estimation, and P1=50% for a highly spin-polarised top electrode, a MR ratio of 115% is obtained.

The predicted MR ratio of over 100% for the spin filter device of the present invention vastly outperforms the highest MR ratios (up to 60%) reported for conventional MTJ devices. Furthermore, since the tunneling barrier embodied in FIG. 2 consists of a wide band-gap semiconductor, exemplified by ZnMEO with a band-gap of 3.2 eV, the resistance-area (RA) product of this device is inherently lower than for the, in prior art used, alumina insulator. In this way the ultra thin barrier thickness regime is avoided. It is estimated that ZnMEO barrier will exhibit RA values matching alumina at more than twice the alumina barrier thickness. This estimate is supported by a recent report on barrier layers of ZnSe, another wide band-gap semiconductor similar to ZnO, with a band-gap of 2.8 eV [6]. Thus, the present invention embodied in FIG. 2, with features described in the preceding text with references to FIGS. 3-4, fulfills the requirements for improved signal-to-noise ratios in MTJ device applications such as MRAM arrays and magneto resistive read heads. Other synergic effects of the present invention will be described in the following.

The magnetic field strength required to reverse the magnetization direction (coercivity) in ferromagnetic semiconductors such as ZnMEO is typically almost two orders of magnitude larger than for permalloy that is commonly used as the top electrode “free” layer in MTJs. This suggests that the spin filter barrier layer in the present invention does not need to be magnetically biased by an underlying antiferromagnetic layer, as is the case for the bottom electrode “fixed” layer in conventional MTJ devices. This vastly simplifies the MTJ device structure. Furthermore, the use of a non-magnetic bottom electrode, in contrast to a ferromagnetic bottom electrode of prior art, opens up a broad selection of conducting materials. This includes metallic conductors such as Cu, Al or Au, but also degenerate semiconductors. For example, the use of n-type Si as a bottom electrode offers, in a direct manner, the important compatibility with Si-processes and CMOS technology. Many reports have demonstrated the achievement of thin continuous ZnO films of good quality by various deposition techniques on Si wafer substrates. Another example offers the very attractive possibility of epitaxial ZnMEO barrier layers through the use of degenerate ZnAlO as a bottom electrode layer. ZnAlO is a semi-metal that is frequently used as conductor in solar cell application and has a perfect crystallographic match to ZnMEO.

### REFERENCES

[1] M. Julliere, Phys. Lett. 54A, 225 (1975)
[2] R. Meservey, and P. M. Tedrow, Phys. Rep. 238, 173 (1994)
[3] Y. Ji, G. J. Strijkers, F. Y. Yang, C. L. Chien, J. M. Byers, A. Anguelouch, G. Xiao, and A. Gupta, Phys. Rev. Lett. 86, 5585 (2001)
[4] W. E. Pickett, and J. S. Moodera, Phys. Today 5, 39 (2001)
[5] A. Mauger, and C. Godart, Phys. Rep. 141, 51 (1986)
[6] X. Jiang, A. F. Panchula, and S. S. P. Parkin, Appl. Phys. Lett. 83, 5244 (2003)

1-10. (canceled)

11. A magnetic tunnel junction having a tunneling barrier layer, said tunneling barrier layer comprising a diluted magnetic semiconductor with spin sensitivity wherein said diluted magnetic semiconductor is a wide band-gap semiconductor exceeding 2.7 eV.

12. A magnetic tunnel junction according to claim 11 comprising a bottom lead coupled to a bottom electrode which is coupled to a bottom electrode which is coupled to a diluted magnetic semiconductor coupled to a top electrode being coupled to a top lead wherein said bottom electrode is non magnetic.

13. A magnetic tunnel junction according to claim 12 wherein said bottom electrode comprises n-type Si.

14. A magnetic tunnel junction according to claim 12 wherein said bottom electrode comprises degenerated AnA1O.

15. A magnetic tunnel junction according to claim 11 wherein said tunnel junction comprises a spin filter device with a Magnetic Resistance (MR) ration exceeding 60%.

16. A magnetic tunnel junction according to claim 11 wherein said diluted magnetic semiconductor comprises ZnMEO.

17. A component comprising a magnetic tunnel junction according to claim 11.

18. A component according to claim 17 which is realized as any of the following components: a non-volatile magnetic random access memory (MRAM), a magneto resistive read head for magnetic disk drives, a spin-valve/magnetic-tunnel transistor, an ultra-fast optical switch, a light emitter with polarization modulated output and a logic processing device.

19. A computer comprising a magnetic tunnel junction according to claim 11.

20. A computer comprising a component according to claim 17.

21. A computer comprising a magnetic tunnel junction according to claim and a component according to claim 17.
